(19) United States
(12) Patent Application Publication
(10) Pub. No.: US 2014/0146489 A1
(43) Pub. Date: May 29, 2014

(54) SURFACE FINISH FOR CONDUCTIVE FEATURES ON SUBSTRATES

(71) Applicant: RF Micro Devices, Inc., Greensboro, NC (US)

(72) Inventors: John August Orlowski, Summerfield, NC (US); Donald Joseph Leahy, Kernersville, NC (US); Thomas Scott Morris, Lewisville, NC (US); David C. Dening, Stokesdale, NC (US); David Jandzinski, Summerfield, NC (US)

(21) Appl. No.: 13/891,809

(22) Filed: May 10, 2013

Related U.S. Application Data
(60) Provisional application No. 61/730,649, filed on Nov. 28, 2012.

(51) Int. Cl. H05K 1/02; H05K 3/38

(52) U.S. Cl. CPC H05K 1/0296; H05K 3/383
USPC 361/748; 174/257; 427/125

(57) ABSTRACT

An electronic substrate includes a non-conductive body and one or more conductive features coupled to the non-conductive body. Each of the conductive features includes a base layer. To preserve the performance and conductivity of the one or more conductive features, each of the conductive features includes a protective layer formed over the base layer. The protective layer may include a first layer of silver formed over the base layer and a second layer of palladium formed over the first layer. By depositing the protective layer over the base layer of each of the conductive features, oxidation and exposure of the conductive features is prevented, or at least substantially reduced, since the first layer and the second layer provide a migration barrier for the metal in the base layer. However, the performance and conductivity of the conductive features are maintained due to the low resistivity of silver and palladium.

### RELATED APPLICATIONS

This application claims the benefit of provisional patent application Ser. No. 61/730,649, filed Nov. 28, 2012, the disclosure of which is hereby incorporated herein by reference in its entirety. The application is also related to the concurrently filed patent application entitled “SURFACE FINISH FOR CONDUCTIVE FEATURES ON SUBSTRATES,” the disclosure of which is hereby incorporated herein by reference in its entirety.

### FIELD OF THE DISCLOSURE

The present disclosure relates to protective finishes for electronic substrates.

### BACKGROUND

Electronic substrates are often used to support and connect electrical components and electronic modules. Generally, an electronic substrate includes a non-conductive body for support, and a plurality of conductive features for connecting the electrical components or electronic modules. The conductive features may be any type of conductive structure exposed at a surface of the non-conductive body and may include contact pads, conductive traces, surface-exposed sections of vias, and/or the like. Electrical components such as resistors, capacitors, inductors, bond wires, and integrated circuits (ICs) are mounted to one or more of the conductive features by a soldering process. For example, the conductive features may include one or more contact pads connected to one another by one or more conductive traces. An IC circuit (such as a semiconductor die) may be mounted on the one or more conductive pads by the soldering process. Accordingly, one or more circuits are formed on the electronic substrate.

The conductive features of an electronic substrate are often created by a copper etching process, wherein a thin copper sheet is laminated onto the non-conductive body and etched to form a connection pattern. The conductive properties and performance characteristics of the conductive features may degrade over time due to oxidation and exposure to the elements. Accordingly, a protective layer is generally deposited onto the one or more conductive features in order to preserve the conductive properties thereof.

FIG. 1A shows a PCB 10 including a non-conductive body 12, a plurality of contact pads 14, and a solder mask 16. The non-conductive body 12 may be located behind the solder mask 16, and may comprise, for example, a laminate material. The plurality of contact pads 14 may comprise copper, and may be formed by the etching process described above. The plurality of contact pads 14 may be adapted to connect one or more features of an electrical component to one another. Additionally and/or alternatively, the plurality of contact pads 14 may be adapted to connect the features of one or more additional electrical components using one or more conductive traces located beneath the solder mask 16 (not shown). Electrical components may be attached to the plurality of contact pads 14 using, for example, a soldering process, wherein tin or another soldering material is melted between the conductive features of an electrical component and each one of the plurality of contact pads 14. The melted material is cooled to form a mechanical and electrical connection between the electrical component and the plurality of contact pads 14. The solder mask 16 may comprise any non-solderable (i.e., non-wettable) material, and may be adapted to partially cover the plurality of contact pads 14 such that an exposed connection pattern is formed that is compatible with a desired electrical component.

FIG. 1B shows a side view of the PCB 10 shown in FIG. 1A, including the non-conductive body 12, the plurality of contact pads 14, and the solder mask 16. As shown in FIG. 1B, the plurality of contact pads 14 is coupled to the non-conductive body 12 and partially covered by the solder mask 16. The portions of the plurality of contact pads 14 exposed through the solder mask 16 are the areas of the plurality of contact pads 14 available for connection to an electrical component, for example, by a soldering process, as discussed above.

FIG. 1C shows a three-dimensional view of the PCB 10 shown in FIG. 1A, including the non-conductive body 12, the plurality of contact pads 14, and the solder mask 16. As shown in FIG. 1C, the plurality of contact pads 14 is partially exposed through the solder mask 16. Due to environmental exposure, the plurality of contact pads 14 may experience oxidation and degradation of their conductive properties, thereby resulting in greater insertion loss associated with each one of the plurality of contact pads 14 and a loss of efficiency for a circuit formed on the PCB 10.

FIG. 2A shows a cross-sectional view of the PCB 10 shown in FIG. 1B, where each one of the plurality of contact pads 14 includes a base layer 18, a first protective layer 20A over the portions of the base layer 18 exposed through the soldering mask 16, a second protective layer 20B over the first protective layer 20A, and a third protective layer 20C over the second protective layer 20B. In this disclosure, the first protective layer 20A, the second protective layer 20B, and the third protective layer 20C are referred to collectively as the protective layer 20. The protective layer 20 is formed using an electroless nickel-electroless palladium-immersion gold (ENEPIG) process. Accordingly, the first protective layer 20A is electroless nickel, the second protective layer 20B is electroless palladium, and the third protective layer 20C is gold. Although the protective layer 20 prevents oxidation and exposure of the underlying base layer 18, the protective layer 20 may also degrade the conductive properties and performance characteristics of each one of the contact pads 14. For example, when soldering an electrical component to the contact pads 14, the protective layer 20 will melt and mix with tin solder applied to the contact pads 14. The resulting amalgamated tin-nickel-palladium-gold solder joint has less-desirable conductive properties and performance characteristics than that of a tin solder joint alone. Accordingly, the insertion loss associated with each one of the contact pads 14 will increase, thereby degrading the efficiency of a circuit formed on the PCB 10.

FIG. 2B shows a cross-sectional view of the PCB 10 shown in FIG. 1B, where each one of the conductive pads 14 includes the base layer 18, a first protective layer 21A over the portions of the base layer 18 exposed through the solder mask 16, and a second protective layer 21B over the first protective layer 21A (the first protective layer 21A and the second protective layer 21B are referred to collectively as protective layer 21). The protective layer 21 is formed using an electroless palladium-immersion gold (EPIC) process. Accordingly, the first protective layer 21A is electroless palladium, and the second protective layer 21B is gold. Although the protective layer 21 prevents oxidation and exposure of the underlying base layer 18, the protective layer 21 may also degrade the conductive properties and performance characteristics of each one of the plurality of contact pads 14. For example, when soldering an electrical component to the plurality of contact pads 14, the protective layer 21 will melt and mix with tin solder applied to the plurality of contact pads 14. The resulting amalgamated tin-palladium-gold solder joint has less desirable conductive properties and performance characteristics than that of a tin solder joint alone. Accordingly, the insertion loss associated with each one of the contact pads 14 will increase, thereby degrading the efficiency of a circuit formed on the PCB 10.

### SUMMARY

An electronic substrate includes a non-conductive body and one or more conductive features coupled to the non-conductive body. Each of the conductive features includes a base layer, which may be made of copper. In order to preserve the performance and conductivity of the one or more conductive features, each of the conductive features includes a protective layer formed over the base layer. The protective layer may include a first layer of silver formed over the base layer and a second layer of palladium formed over the first layer. By depositing the protective layer over the base layer of each of the conductive features, oxidation and exposure of the conductive features is prevented, or at least substantially reduced, since the first layer and second layer provide a migration barrier for the metal (for example, copper) in the base layer. However, the performance and conductivity of the conductive features are maintained due to the low resistivity of silver and palladium.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic representation of a printed circuit board (PCB).

FIG. 1B is a schematic representation of a side view of the PCB shown in FIG. 1A.

FIG. 1C is a three-dimensional view of the PCB shown in FIG. 1A.

FIG. 2A is a schematic representation of a PCB with a related art protective layer.

FIG. 2B is a schematic representation of a PCB with a related art protective layer.

FIG. 3A is a schematic representation of an electronic substrate with a protective layer according to one embodiment of the present disclosure.

FIG. 3B is a schematic representation of an electronic substrate with a protective layer according to an additional embodiment of the present disclosure.

FIG. 4 is a schematic representation of a flip chip electrical component suitable for attachment to the electronic substrate shown in FIG. 3A and FIG. 3B.

FIG. 5 is a schematic representation showing the alignment of the electronic substrate and the flip chip electrical component according to one embodiment of the present disclosure.

FIG. 6 is a schematic representation showing the flip chip electrical component in contact with the contact pads on a first surface of the electronic substrate.

FIG. 7 is a schematic representation showing the flip chip electrical component mounted to the electronic substrate after the flip chip electrical component is soldered to the contact pads on the first surface of the electronic substrate.

FIG. 8 is a schematic representation showing an electronic module, wherein the electronic substrate shown in FIG. 7 is part of the electronic module.

FIG. 9 is a schematic representation of the electronic module and a PCB, wherein the electronic module is to be mounted on the PCB.

FIG. 10 is a schematic representation showing contact pads on a second side of the electronic substrate in the electronic module in contact with contact pads on the PCB.

FIG. 11 is a schematic representation showing the electronic module mounted to the other PCB after the contact pads on the second surface of the electronic substrate in the electronic module are soldered to the contact pads on the PCB.

FIG. 12 shows the process for creating the electronic substrate shown in FIG. 3A with the protective layer according to one embodiment of the present disclosure.

FIG. 13 shows a process for creating the electronic substrate with the protective layer shown in FIG. 3B according to an additional embodiment of the present disclosure.

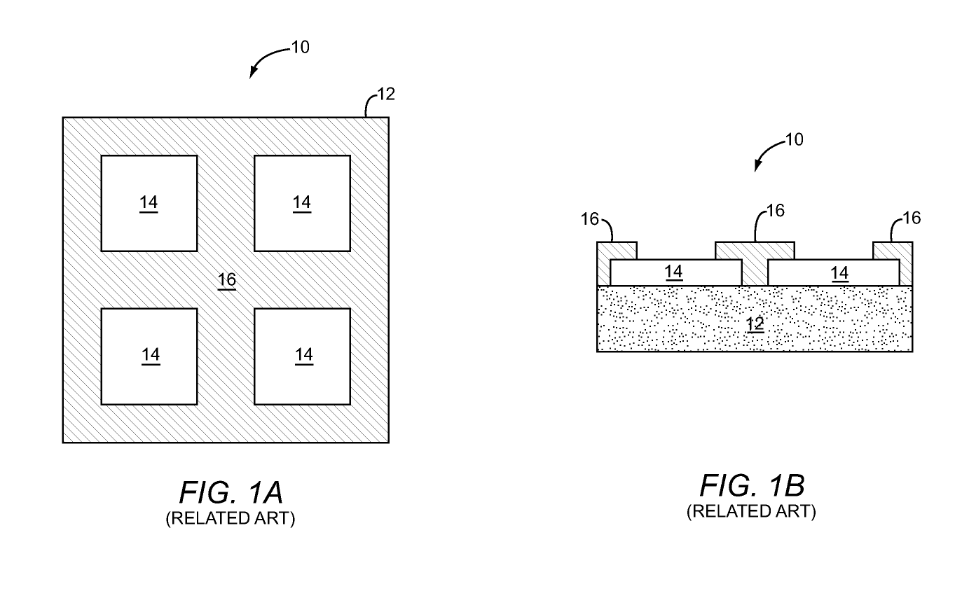

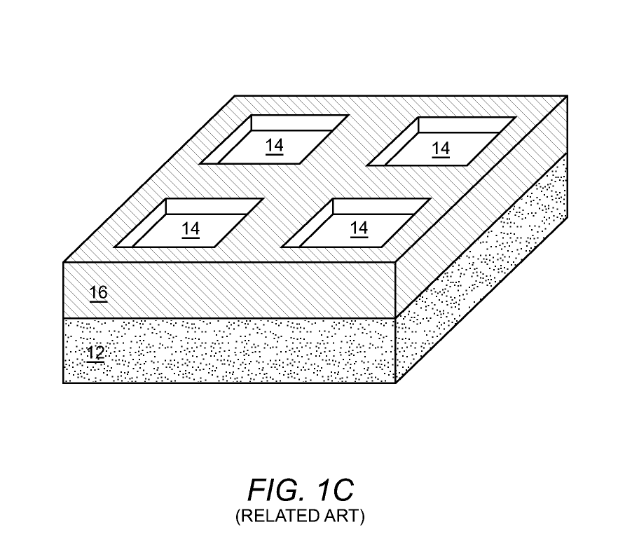

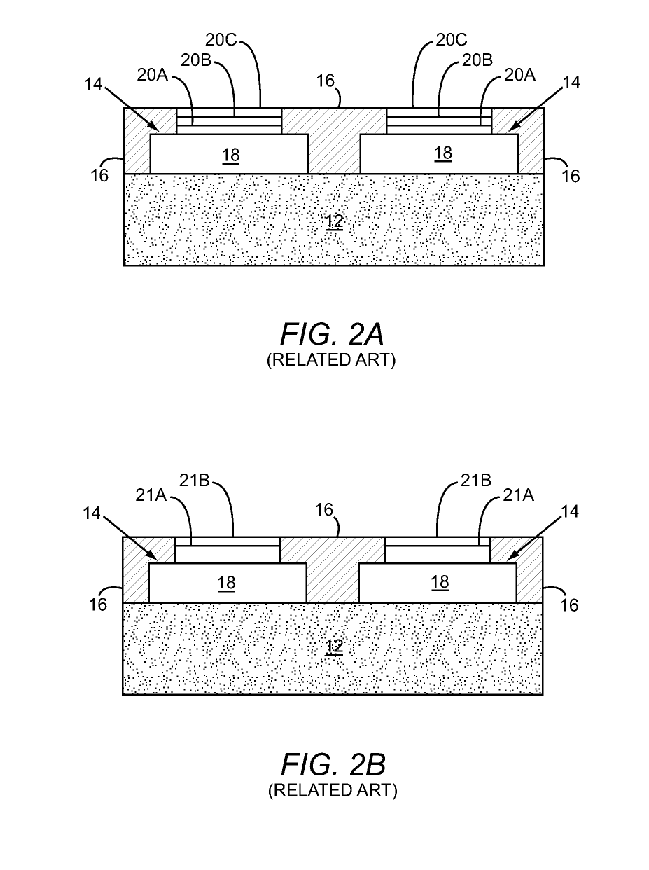

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

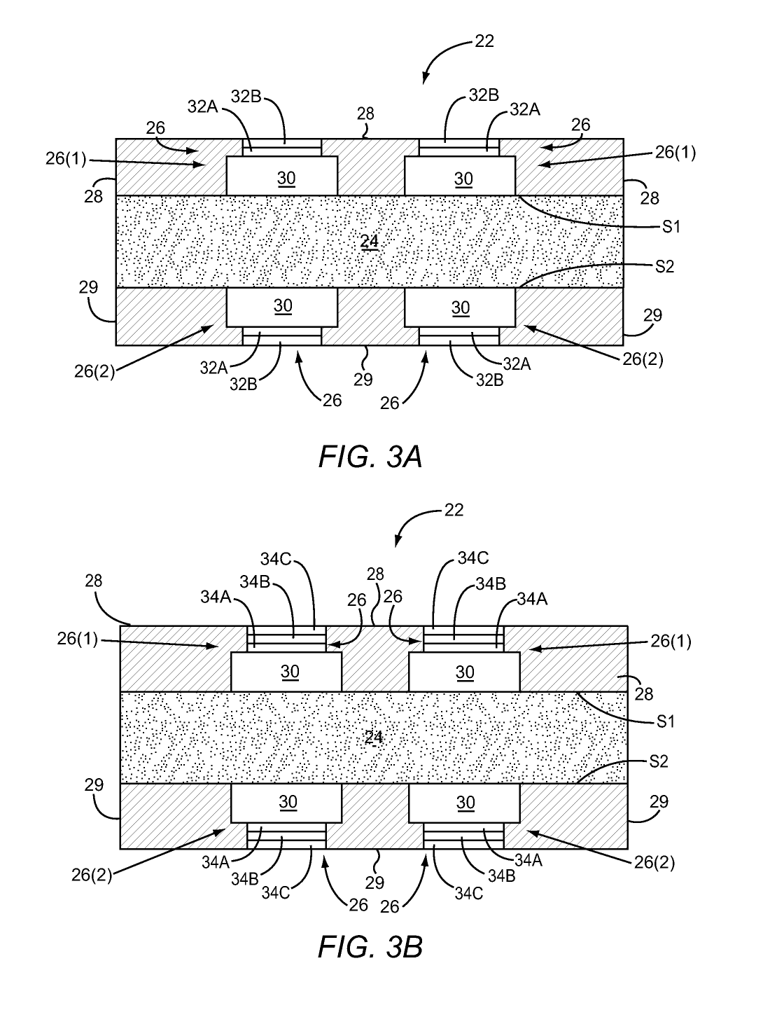

Turning now to FIG. 3A, a cross-sectional view of an electronic substrate 22 is shown according to one embodiment of the present disclosure. According to this embodiment, the electronic substrate 22 includes a non-conductive body 24, one or more contact pads 26, a solder mask 28, and a solder mask 29. Each one of the contact pads 26 may include a base layer 30, a first protective layer 32A over the base layer 30, and a second protective layer 32B over the first protective layer 32A. In this disclosure, the first protective layer 32A and the second protective layer 32B are referred to collectively as the protective layer 32. The non-conductive body 24 may comprise, for example, a laminate material, a fiber material, a glass material, a ceramic material, and/or the like. The base layer 30 may comprise copper, and may be formed by an etching process, wherein a copper sheet is laminated onto the non-conductive body 24 and etched to form a connection pattern.

The non-conductive body 24 defines a first surface S1 and a second surface S2. In this embodiment, the first surface S1 is on a first side of the non-conductive body 24, while the second surface S2 is on a second side of the non-conductive body 24. Accordingly, the second surface S2 is oppositely disposed from the first surface S1. The first side of the non-conductive body 24 with the first surface S1 may be generally referred to as a component side of the non-conductive body 24. The second side of the non-conductive body 24 with the surface S2 may be generally referred to as a connection side of the non-conductive body 24. The contact pads 26 include a first set of contact pads 26(1) coupled to the non-conductive body 24 on the first surface S1, which is at the component side of the non-conductive body 24. Since the first set of contact pads 26(1) is on the first surface S1, the first set of contact pads 26(1) is exposed at the first surface S1 of the non-conductive body 24. In addition, the contact pads 26 include a second set of contact pads 26(2) coupled to the non-conductive body 24 on the second surface S2, which is at the connection side of the non-conductive body 24. Since the second set of contact pads 26(2) is on the second surface S2, the second set of contact pads 26(2) are exposed at the second surface S2 of the non-conductive body 24.

The contact pads 26 may be adapted to connect one or more features of an electrical component to one another or to features of one or more additional electronic components through one or more conductive traces. Electrical components and/or external circuitry may be attached to the contact pads 26 using, for example, a soldering process, wherein tin or another solder material is melted between the conductive features of an electrical component and each one of the contact pads 26, and is cooled to form a mechanical and electrical connection between the electrical component and the contact pads 26. In the embodiment illustrated in FIG. 3A, the first set of contact pads 26(1) is exposed by the solder mask 28 on the first surface 51. The solder mask 28 may comprise any non-solderable (i.e., non-wettable) material, and may be adapted to partially cover the first set of contact pads 26(1) such that an exposed connection pattern that is compatible with a desired electrical component is formed. As explained in further detail below, the electronic substrate 22 may be provided within an electronic module as a mounting apparatus for one or more electronic components. In this case, the electronic module would encapsulate the electronic components soldered to the first set of contact pads 26(1) on the first surface 51, which would thereby enclose the first surface 51 on the component side. However, the second set of contact pads 26(2) on the second surface S2 may be externally exposed by the electronic module. In this manner, external circuitry can make connections to the electronic components from the connection side by soldering to the second set of contact pads 26(2). The second set of contact pads 26(2) is exposed by the solder mask 29.

With regard to the protective layer 32 in FIG. 3A for each one of the contact pads 26, the first protective layer 32A is silver and the second protective layer 32B is palladium. The first protective layer 32A may be deposited by an immersion silver process, and may be approximately 0.5 μm to 2.0 μm thick. The second protective layer 32B may be deposited by an immersion palladium process, and may be approximately 0.05 μm to 0.2 μm thick. The use of an immersion silver-immersion palladium protective layer 32 prevents oxidation and exposure of the underlying base layer 30, thereby maintaining the conductive properties and performance characteristics of the contact pads 26. More specifically, the first protective layer 32A of silver provides a good barrier so that copper in the base layer 30 does not migrate to a surface of the contact pad 26 and cause oxidation. Nevertheless, silver still allows for some copper migration. The second protective layer 32B of palladium that provides an improvement that further inhibits copper migration to the surface of the contact pad 26. Palladium can be an even better barrier for copper migration. However, the first protective layer 32A of silver allows the second protective layer 32B of palladium to be provided at a desired thickness. Since both silver and palladium have low resistivities, the immersion silver-immersion palladium protective layer 32 does not significantly affect the conductive properties or the performance characteristics of the contact pads 26. Accordingly, the insertion loss associated with each one of the contact pads 26 is reduced compared to the insertion loss associated with a contact pad using a traditional protective layer, thereby increasing the efficiency of a circuit formed on the electronic substrate 22.

According to one embodiment, the electronic substrate 22 shown in FIG. 3A is for use with radio frequency (RF) signals. Because the protective layer 32 does not contain nickel, the performance of an RF circuit formed on the electronic substrate 22 is improved.

FIG. 3B shows a cross-sectional view of an electronic substrate 22 according to an additional embodiment of the present disclosure. According to this embodiment, the electronic substrate 22 includes the non-conductive body 24, the contact pads 26, and the solder mask 28. Each one of the contact pads 26 may include the base layer 30, a first protective layer 34A over the base layer 30, a second protective layer 34B over the first protective layer 34A, and a third protective layer 34C over the second protective layer 34B. In this disclosure, the first protective layer 34A, the second protective layer 34B, and the third protective layer 34C are referred to collectively as the protective layer 34. As in the embodiment described above in FIG. 3A, the first set of contact pads 26(1) in FIG. 3B is coupled to the non-conductive body 24 on the first surface S1 and the second set of contact pads 26(2) in FIG. 3B is coupled to the non-conductive body 24 on the second surface S2.

According to one embodiment, the first protective layer 34A is made of silver, the second protective layer 34B is made of palladium, and the third protective layer 34C is made of gold. The first protective layer 34A may be deposited by an immersion silver process, and may be approximately 0.5 μm to 0.2 μm thick. The second protective layer 34B may be approximately 0.5 μm to 0.2 μm thick. Additionally, the third protective layer 34C may be approximately 0.05 μm to 0.15 μm thick. Using the immersion silver layer, the immersion palladium layer, and the immersion gold layer to form the protective layer 34 prevents oxidation and exposure of the underlying base layer 30. In particular, the third protective layer 34C adds an additional barrier to prevent copper migration from the base layer 30 to a surface of the contact pad 26. Since gold has a low resistivity, the third protective layer 34C does not significantly affect the conductive properties and performance characteristics of the contact pads 26. As mentioned above, the immersion silver layer and the immersion palladium layer that form the protective layer 34 do not significantly affect the conductive properties or performance characteristics of the contact pads 26. Accordingly, the insertion loss associated with each one of the contact pads 26 is reduced compared to the insertion loss associated with a contact pad using a traditional protective layer, thereby increasing the efficiency of a circuit formed on the electronic substrate 22. Furthermore, the third protective layer 34C of immersion gold allows for more reliable and predictable wire bonds to the contact pads 26 in FIG. 3B.

The embodiment of the electronic substrate 22 shown in FIG. 3B is for use with RF signals. Because the protective layer 34 does not contain nickel, the performance of an RF circuit formed on the electronic substrate 22 is improved.

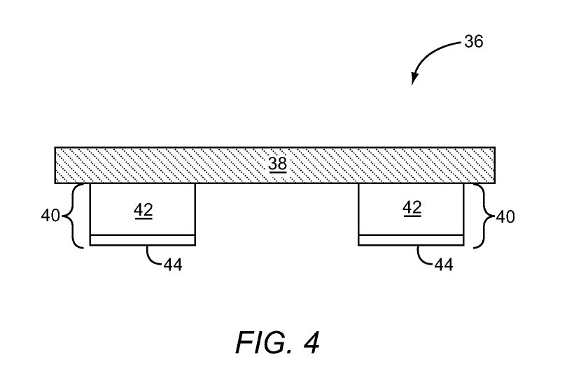

With reference to FIGS. 4-8, FIGS. 4-8 graphically illustrate a process for attaching an integrated circuit (IC) component to the electronic substrate 22 shown in FIG. 3A. The IC component is provided over the first surface S1 on the component side of the non-conductive body 24. First, the IC component is provided for attachment to the electronic substrate 22. FIG. 4 shows an exemplary flip chip electronic component 36 suitable for mounting on the electronic substrate 22 shown in FIGS. 3A and 3B. In this embodiment, the flip chip electronic component 36 may include a die 38 and one or more conductive pillars 40. The die 38 has been fabricated to provide an IC. Each one of the conductive pillars 40 may include a base layer 42 and a solder layer 44. According to one embodiment, the base layer 42 is comprised of copper, and the solder layer 44 is comprised of tin.

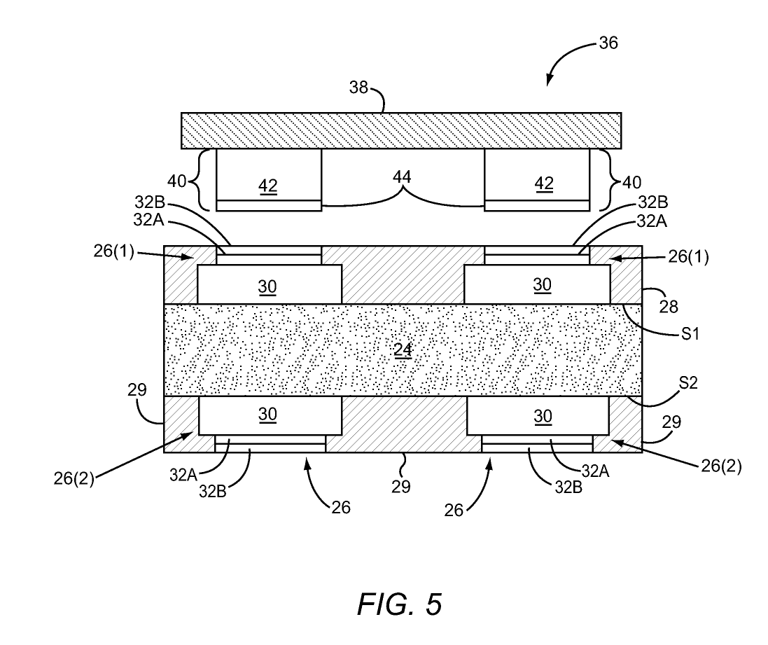

Next, the electronic substrate 22 and the flip chip electronic component 36 are aligned. FIG. 5 shows a cross-sectional view of the electronic substrate 22 shown in FIG. 3A further including the flip chip electronic component 36 for attachment to the electronic substrate 22. As shown in FIG. 4, the conductive pillars 40 of the flip chip electronic component 36 are aligned with the first set of contact pads 26(1) on the first surface S1 of the electronic substrate 22 from the component side.

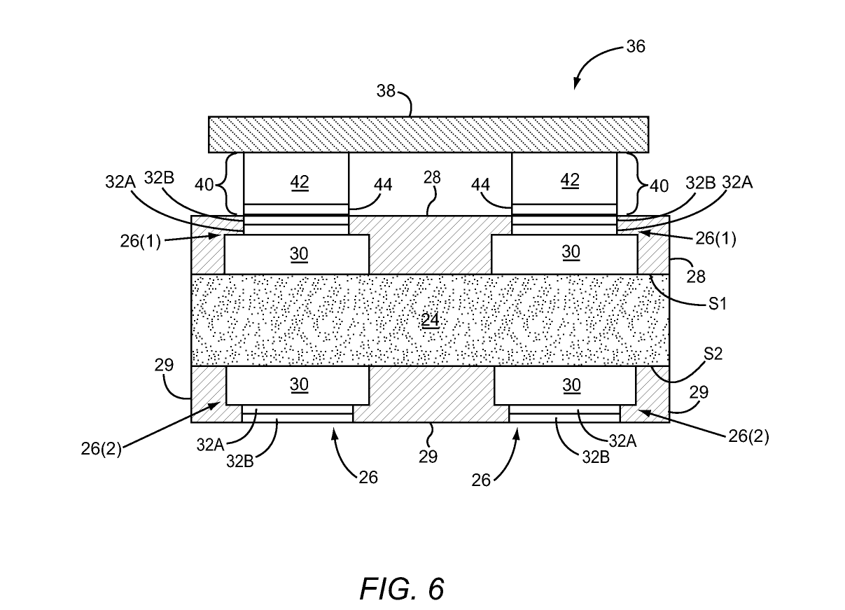

The conductive pillars 40 of the flip chip electronic component 36 are then placed in physical contact with the first set of contact pads 26(1) of the electronic substrate 22. FIG. 6 shows a cross-sectional view of the electronic substrate 22 shown in FIG. 5, wherein the conductive pillars 40 of the flip chip electronic component 36 are in contact with the first set of contact pads 26(1) of the electronic substrate 22. In particular, the solder layer 44 of the conductive pillars 40 on the flip chip electronic component 36 contact the second protective layer 32B of the contact pads 26 on the electronic substrate 22.

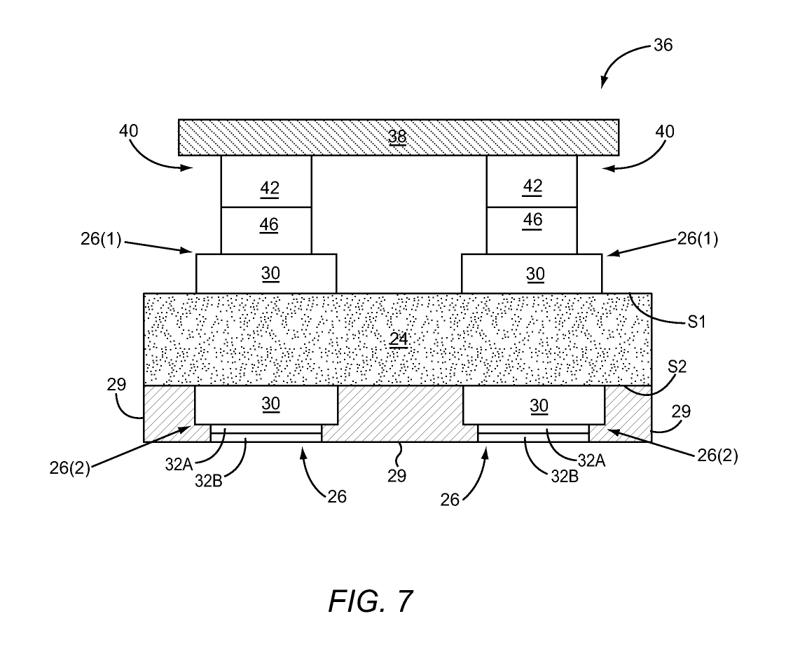

A soldering process is then performed in order to electrically and physically couple the flip chip electronic component 36 and the electronic substrate 22. FIG. 7 shows a cross-sectional view of the electronic substrate 22 shown in FIG. 6, wherein the conductive pillars 40 of the flip chip electronic component 36 are connected to the first set of contact pads 26(1) of the electronic substrate 22 through one or more solder joints 46. According to one embodiment, the flip chip electronic component 36 is attached to the electronic substrate 22 using a soldering process, wherein the conductive pillars 40 of the flip chip electronic component 36 and the first set of contact pads 26(1) of the electronic substrate 22 are heated such that the solder layer 44 and the protective layer 32 reflow and melt together, then are cooled to form the one or more solder joints 46. During the soldering process, the protective layer 32 is substantially dissolved. The resulting solder joints 46 are formed of an amalgamated tin-silver-palladium. According to one embodiment, the base layer 30 of the contact pads 26 is copper. The resultant connections between the copper base layer 30 and the amalgamated tin-silver-palladium solder joints 46 have desirable conductive properties and performance characteristics, thereby contributing to the efficiency of a circuit formed on the electronic substrate 22. After the conductive pillars 40 have been soldered to the first set of contact pads 26(1) of the electronic substrate 22, the solder mask 28 may be removed, as shown in FIG. 7, or they may remain.

Although FIG. 7 shows the electronic substrate 22 attached to the flip chip electronic component 36, any electrical component including any type of mounting topology may be used without departing from the principles of the present disclosure. For example, the electronic substrate 22 may be attached to a bumped die component, a wire bonded electronic component, a ball grid array component, a small outline integrated circuit, or the like. Finally, the electronic substrate 22 is used as a mounting structure within an electronic module. To form the electronic module, an overmold layer is provided in order to stabilize the flip chip electronic component 36 on the component side.

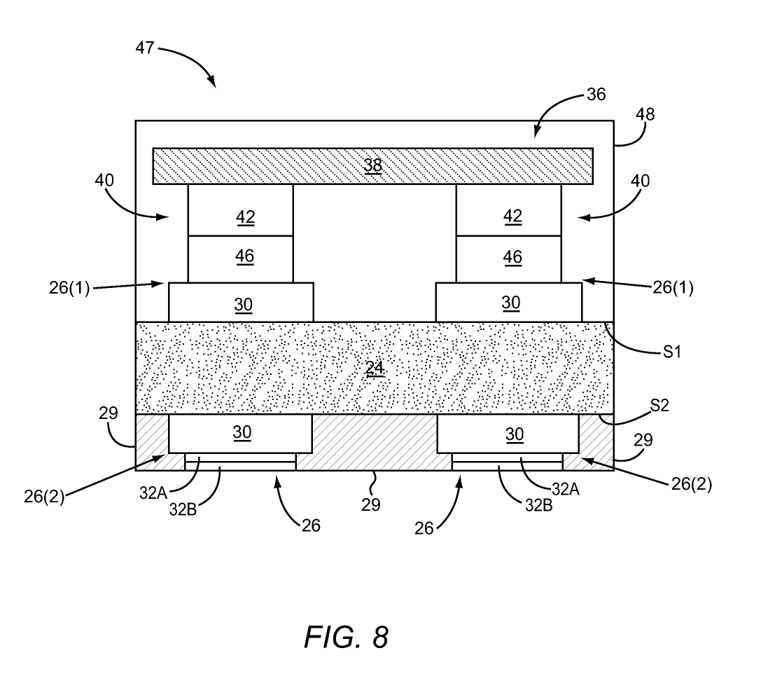

FIG. 8 shows a cross-sectional view of an electronic module 47 where the flip chip electronic component 36 soldered to the electronic substrate 22 shown in FIG. 7 is enclosed by an overmold layer 48 over the first surface S1 of the non-conductive body 24. The electronic substrate 22 illustrated in FIG. 8 is thus provided as a mounting structure for electronic components in the electronic module 47. The overmold layer 48 of the electronic module 47 may provide support and rigidity to the electronic substrate 22, as well as stabilize the flip chip electronic component 36. Additionally, the overmold layer 48 may be formed from a dielectric material, such as silicon oxide (SiOₓ), to encapsulate the flip chip electronic component 36. As a result, the overmold layer 48 encapsulates and helps to electromagnetically isolate the flip chip electronic component 36 from electromagnetic noise. Additionally, an electromagnetic shield (not shown) may be formed on the overmold layer 48 to further electromagnetically isolate the flip chip electronic component 36. Accordingly, the electronic substrate 22 and the attached components are protected within the electronic module 47. As shown in FIG. 8, the overmold layer 48 encloses the flip chip electronic component 36 and the component side of the non-conductive body 24.

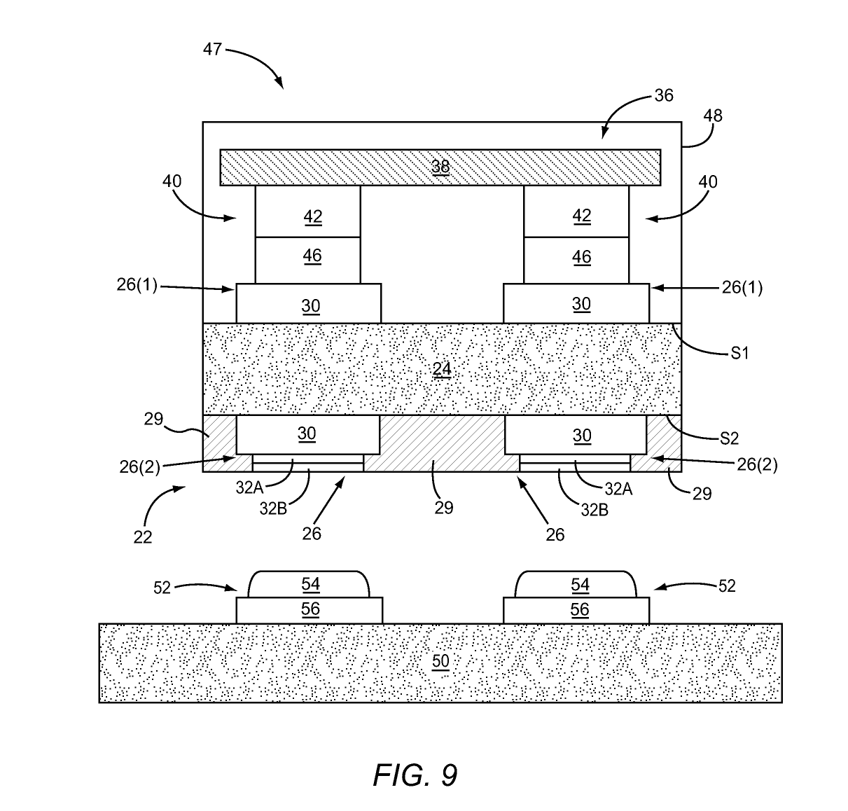

With reference to FIGS. 9-11, FIGS. 9-11 graphically illustrate a process for attaching the electronic module 47 shown in FIG. 8 to another electronic substrate 50. In this embodiment, the other electronic substrate 50 is a printed circuit board (PCB). The electronic substrate 50 may be configured to mount various electronic modules 47 that enclose electronic components with different types of ICs. For example, various electronic modules 47 may be mounted on the electronic substrate so that an RF transceiver is provided by the electronic substrate 50. In one embodiment, the IC formed in the die 38 of the flip chip electronic component 36 is a power amplifier configured to amplify an RF signal. The electronic module 47 may be mounted on the electronic substrate 50 so that the flip chip electronic component 36 is part of the RF transceiver.

As shown in FIG. 9, the second set of contact pads 26(2) on the second surface S2 of the electronic substrate 22 are externally exposed from the electronic module 47. In this manner, external connections can be made to the flip chip electronic component 36 and other circuitry within the electronic module 47 from the connection side of the non-conductive body 24. First, the electronic module 47 is provided for attachment to the electronic substrate 50. In this embodiment, the electronic substrate 50 includes contact pads 52 for connecting to the second set of contact pads 26(2). Each of the contact pads 52 includes a base layer 54 made of copper and a solder layer 56 made of tin. In order to mount the electronic module 47, the second surface S2 on the connection side of the non-conductive body 24 is positioned so that the second set of contact pads 26(2) is aligned with the contact pads 52. To protect the second surface S2, the solder mask 29 is placed over the second surface S2. The solder mask 29 includes apertures that expose portions of the second set of contact pads 26(2) for soldering.

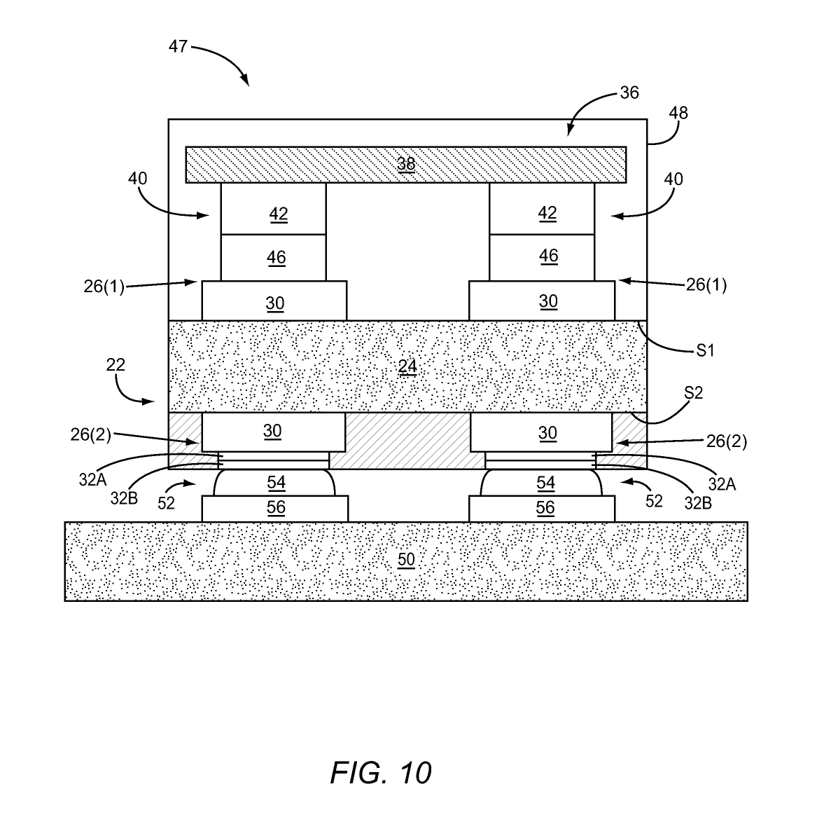

FIG. 10 shows a cross-sectional view of the electronic module 47 and the electronic substrate 50 illustrated in FIG. 9, where the second set of contact pads 26(2) are placed in contact with the contact pads 52 of the electronic substrate 50. In particular, the solder layer 56 of the contact pads 52 is provided in contact with the second protective layer 32B of the second set of contact pads 26(2) on the second surface S2 at the connection side of the electronic substrate 22. A soldering process is then performed in order to electrically and physically couple the electronic module 47 and the electronic substrate 50.

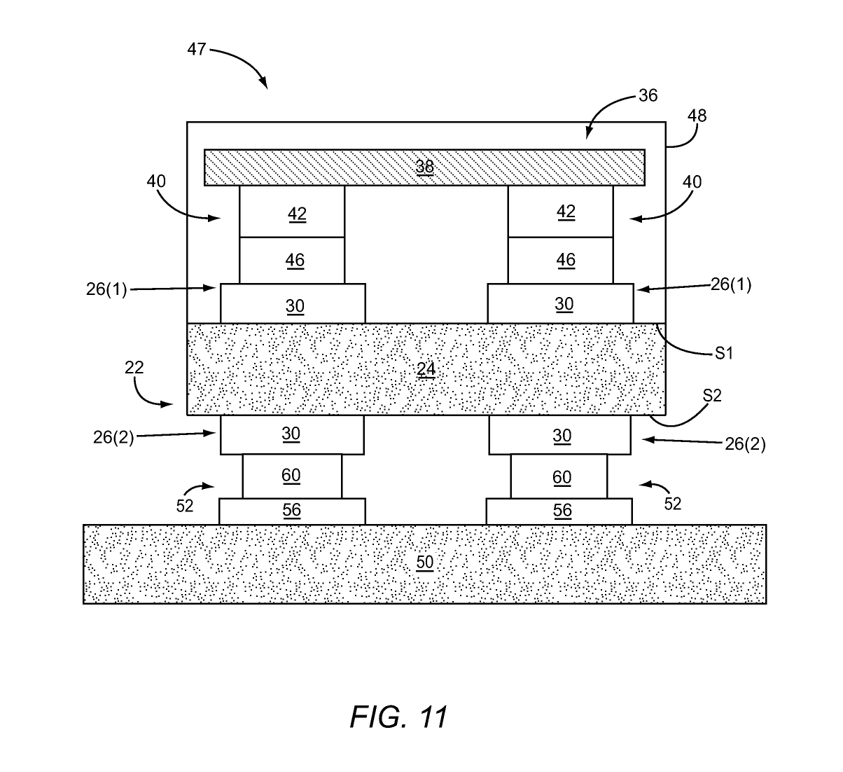

FIG. 11 shows a cross-sectional view of the electronic module 47 and the electronic substrate 50 shown in FIG. 10, wherein the second set of contact pads 26(2) of the electronic substrate 22 in the electronic module 47 are connected to the contact pads 52 of the electronic substrate 50 through one or more solder joints 60. According to one embodiment, the electronic module 47 is attached to the electronic substrate 50 using a soldering process, wherein the second set of contact pads 26(2) on the second surface S2 at the connection side and the contact pads 52 of the electronic substrate 50 are heated such that the solder layer 56 and the protective layer 32 reflow and melt together, then are cooled to form the one or more solder joints 60. During the soldering process, the protective layer 32 is substantially dissolved. The resulting solder joints 60 are formed of an amalgamated tin-silver-palladium. According to one embodiment, the base layer 30 of the second set of contact pads 26(2) is copper.

The resultant connections between the copper base layer 30 and the amalgamated tin-silver-palladium solder joints 60 have desirable conductive properties and performance characteristics, thereby contributing to the efficiency of the IC in the electronic module 47. After soldering to the second set of contact pads 26(2), the solder mask 29 may be removed, as shown in FIG. 11, or it may remain.

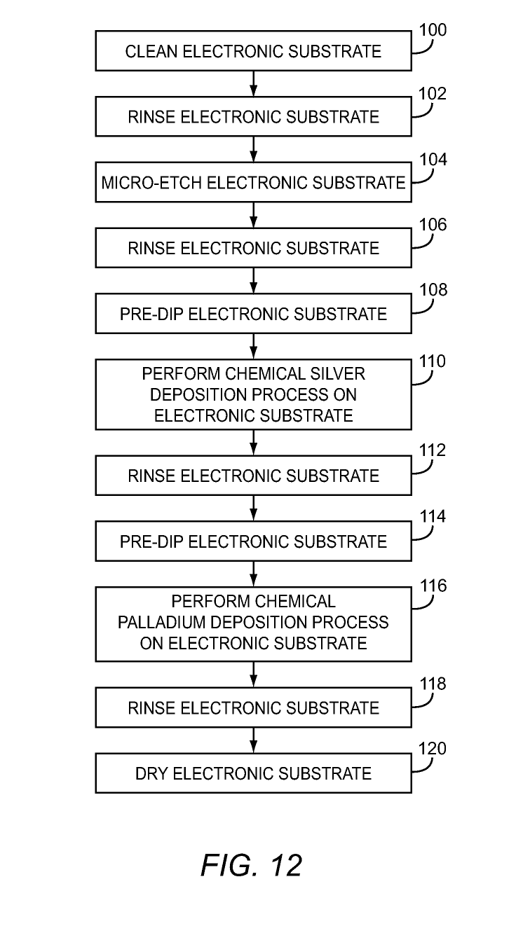

FIG. 12 illustrates a process for forming the protective layer 32 of each one of the contact pads 26 shown in FIG. 3A. First, the electronic substrate 22 is cleaned (step 100). According to one embodiment, the electronic substrate 22 is soaked in an acid cleaner. Next, the electronic substrate 22 is rinsed (step 102) with water. The electronic substrate 22 is then chemically micro-etched (step 104). This may include soaking the electronic substrate 22 in an acid solution in order to etch a small amount of conductive material off of the base layer 30 of each one of the contact pads 26. The electronic substrate 22 is then rinsed again (step 106), and is pre-dipped (step 108) in preparation for a chemical silver deposition process (step 110). The pre-dipping may comprise dipping the electronic substrate 22 into an acidic solution in order to remove any water from the electronic substrate 22 as well as to prepare the electronic substrate 22 for the chemical silver deposition process. The chemical silver deposition process may comprise soaking or dipping the electronic substrate 22 in a silver bath. As the electronic substrate 22 is exposed to the silver bath, conductive material from the base layer 30 of each one of the contact pads 26 is slowly dissolved and replaced with silver in order to form the first protective layer 32A of silver over the base layer 30 of each one of the contact pads 26. The first protective layer 32A of silver is thus formed on the base layer 30. In this embodiment, the chemical silver deposition process is an immersion silver deposition process. The electronic substrate 22 is then rinsed again (step 112), and is pre-dipped (step 114) in preparation for a chemical palladium deposition process (step 116). The chemical palladium deposition process may comprise soaking or dipping the electronic substrate 22 in a palladium bath. As the electronic substrate 22 is exposed to the palladium bath, the first protective layer 32A of silver over the base layer 30 of each one of the contact pads 26 is plated with the second protective layer 32B of palladium. In this embodiment, the chemical palladium deposition process is an immersion palladium deposition process. The second protective layer 32B of palladium is thus formed on the first protective layer 32A. The electronic substrate 22 is then rinsed (step 118) and dried (step 120). The resulting protective layer 32 maintains the conductive properties and performance characteristics of the contact pads 26, thereby contributing to the efficiency of a circuit formed on the electronic substrate 22.

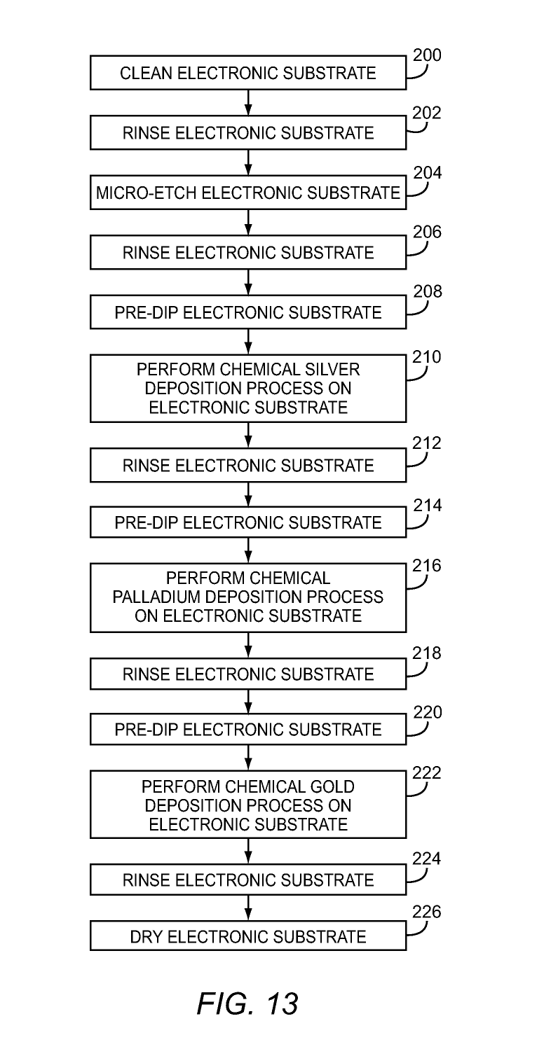

FIG. 13 illustrates a process for forming the protective layer 34 shown in FIG. 3B. First, the electronic substrate 22 is cleaned (step 200). According to one embodiment, the electronic substrate 22 is soaked in an acid cleaner. Next, the electronic substrate 22 is rinsed (step 202) with water. The electronic substrate 22 is then chemically micro-etched (step 204). This may include soaking the electronic substrate in an acid solution in order to etch a small amount of conductive material off of the base layer 30 of each one of the contact pads 26. The electronic substrate 22 is then rinsed again (step 206), and is pre-dipped (step 208) in preparation for a chemical silver deposition process (step 210). The pre-dipping may comprise dipping the electronic substrate 22 into an acidic solution in order to remove any water from the electronic substrate 22 as well as to prepare the electronic substrate 22 for the chemical silver deposition process. The chemical silver deposition process may comprise soaking or dipping the electronic substrate 22 in a silver bath. As the electronic substrate 22 is exposed to the silver bath, conductive material from the base layer 30 of each one of the contact pads 26 is slowly dissolved and replaced with silver in order to form the first protective layer 34A of silver over the base layer 30 of each one of the contact pads 26. In this embodiment, the first protective layer 34A of silver is formed on the base layer 30. In this embodiment, the chemical silver deposition process is an immersion silver deposition process. The electronic substrate 22 is then rinsed again (step 212), and is pre-dipped (step 214) in preparation for a chemical palladium deposition process (step 216). The chemical palladium deposition process may comprise soaking or dipping the electronic substrate 22 in a palladium bath. As the electronic substrate 22 is exposed to the palladium bath, the first protective layer 34A of silver over the base layer 30 of each of the contact pads 26 is plated with the second protective layer 34B of palladium. In this embodiment, the second protective layer 34B is thus formed on the first protective layer 34A. In this embodiment, the chemical palladium deposition process is an immersion palladium deposition process. The electronic substrate 22 is then rinsed again (step 218), and is pre-dipped (step 220) in preparation for a chemical gold deposition process (step 222). The chemical gold deposition process may comprise soaking or dipping the electronic substrate 22 in a gold bath. As the electronic substrate 22 is exposed to the gold bath, the second protective layer 34B of palladium over the first protective layer 34A of each one of the contact pads 26 is plated with the third protective layer 34C of gold. In this embodiment, the third protective layer 34C is thus formed on the second protective layer 34B. In this embodiment, the chemical gold deposition process is an electroless gold deposition process. Next, the electronic substrate 22 is rinsed (step 224). Finally, the electronic substrate 22 is dried (step 226). The resulting protective layer 34 of each one of the contact pads 26 maintains the conductive properties and performance characteristics of the contact pads 26, thereby contributing to the efficiency of a circuit formed on the electronic substrate 22.

The immersion processes described above use a chemical displacement reaction in which a metal from an aqueous solution of a metallic salt replaces a metal in a metallic base. Alternatively and/or additionally, autocatalytic or electroless processes that deposit a metal from an aqueous solution of a metallic salt on a metal in a metallic base using an reducing agent to donate electrons may be used. While electroplating can be also used to provide the protective layer 32 and the protective layer 34, electroplating generally requires busing, which increases the amount of space required to form connections. Using chemical-based deposition processes avoids the use of busing and has been shown to reduce connection points by 100 μm to 200 μm. Accordingly, the immersion silver process described above with regard to FIGS. 12 and 13 could be replaced with an electroless silver deposition process. Other chemical silver deposition processes, such as an autocatalytic silver deposition process, may also be utilized. Similarly, the immersion palladium process described above with regard to FIGS. 12 and 13 can be replaced with an electroless palladium deposition process. Other chemical palladium deposition processes, such as an autocatalytic palladium deposition process, may also be utilized. Finally, the electroless gold deposition process described above in FIG. 13 could be replaced with an immersion gold deposition process. Other chemical gold deposition processes, such as an autocatalytic gold deposition process, may also be utilized. Preparatory procedures may also be different if electroless deposition processes (or any other chemical deposition processes) are being used to form the protective layer 32 and the protective layer 34.

Those skilled in the art will recognize improvements and modifications to the preferred embodiments of the present disclosure. All such improvements and modifications are considered within the scope of the concepts disclosed herein and the claims that follow.

What is claimed is:

1. An electronic substrate comprising:
a non-conductive body; and
a conductive feature coupled to the non-conductive body, wherein the conductive feature comprises a base layer and a protective layer formed over the base layer, the protective layer comprising a first layer of silver and a second layer of palladium formed over the first layer of silver.

2. The electronic substrate of claim 1 wherein the first layer of silver is formed on the conductive feature.

3. The electronic substrate of claim 1 wherein the second layer of palladium is formed on the first layer of silver.

4. The electronic substrate of claim 3 wherein the first layer of silver is formed on the base layer.

5. The electronic substrate of claim 4 wherein the base layer is made of copper.

6. The electronic substrate of claim 1 wherein the protective layer further comprises a third layer of gold formed over the second layer of silver.

7. The electronic substrate of claim 6 wherein:
the first layer of silver is formed on the base layer;
the second layer of palladium is formed on the first layer of silver; and
the third layer of gold is formed on the second layer of palladium.

8. The electronic substrate of claim 1 wherein the base layer is of copper.

9. The electronic substrate of claim 1 further comprising a second conductive feature coupled to the non-conductive body, the second conductive feature comprising a second base layer and a second protective layer formed over the second base layer.

10. The electronic substrate of claim 9 wherein:
the non-conductive body defines a first surface and a second surface oppositely disposed from the first surface;
the base layer is provided on the first surface; and
the second base layer is provided on the second surface.

11. The electronic substrate of claim 1 wherein the conductive feature is a contact pad.

12. The electronic substrate of claim 1 wherein the electronic substrate is adapted for use with a flip chip electronic component.

13. The electronic substrate of claim 1 wherein the electronic substrate is adapted to be a part of an electronic module.

14. The electronic substrate of claim 1 wherein the first layer of silver is approximately 0.5 μm to 2.00 μm thick.

15. The electronic substrate of claim 1 wherein the second layer of palladium is approximately 0.05 μm to 0.20 μm thick.

16. An electronic module comprising:
an electronic substrate comprising:
a non-conductive body that defines a first surface and a second surface oppositely disposed to the first surface, wherein the second surface is exposed externally from the electronic module;
a first conductive feature mounted on the first surface;
a second conductive feature mounted on the second surface, the second conductive feature including a base layer and a protective layer formed over the base layer, wherein the protective layer comprises a first layer of silver and a second layer of palladium formed over the first layer of silver;
an electronic component soldered to the first conductive feature; and
an overmold formed over the first surface to encapsulate the electronic component.

17. A process for applying a protective finish to an electronic substrate comprising:
preparing the electronic substrate for an chemical silver process;
performing the immersion silver process on the electronic substrate;
preparing the electronic substrate for an immersion palladium process; and
performing the immersion palladium process on the electronic substrate.

18. The process of claim 17 wherein preparing the electronic substrate for the immersion silver process comprises:
cleaning the electronic substrate;
rinsing the electronic substrate;
micro-etching the electronic substrate;
rinsing the electronic substrate; and
pre-dipping the electronic substrate in an acid solution.

19. The process of claim 17 wherein preparing the electronic substrate for the immersion palladium process comprises rinsing the electronic substrate and pre-dipping the electronic substrate in an acid solution.

20. The process of claim 17 further comprising:
preparing the electronic substrate for an immersion gold process; and
performing the immersion gold process on the electronic substrate.

21. A process of applying a surface finish to a conductive feature of an electronic substrate comprising:
performing a chemical silver deposition process on the electronic substrate; and
performing a chemical palladium deposition process on the electronic substrate.

22. The process of claim 21 wherein the chemical palladium deposition process is performed after the chemical silver deposition process.

23. The process of claim 21 wherein the chemical silver deposition process is an immersion silver process.

24. The process of claim 21 wherein the chemical silver deposition process is an electroless silver deposition process.

25. The process of claim 21 wherein the chemical palladium deposition process is an immersion palladium process.

26. The process of claim 21 wherein the chemical palladium deposition process is an electroless palladium deposition process.

27. The process of claim 21 further comprising performing a chemical gold deposition process.

28. The process of claim 27 wherein:
the chemical palladium deposition process is performed after the chemical silver deposition process; and
the chemical gold deposition process is performed after the chemical palladium deposition process.

29. The process of claim 27 wherein the chemical gold deposition process is an immersion gold process.

30. The process of claim 27 wherein the chemical gold deposition process is an electroless gold deposition process.
